(19) United States
(12) Patent Application Publication
(10) Pub. No.: US 2007/0205921 A1
(43) Pub. Date: Sep. 6, 2007

(54) Four-Symbol Parallel Viterbi Decoder

(75) Inventor: Sergei Sawitzki, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,646

(22) PCT Filed: Apr. 1, 2005
(86) PCT No.: PCT/IB05/51098

§ 371 Date: Oct. 4, 2006

Related U.S. Application Data
(60) Provisional application No. 60/559,511, filed on Apr. 5, 2004.

(51) Int. Cl. H03M 7/00

(52) U.S. Cl. 341/50

(57) ABSTRACT

High-speed decoding with minimal footprint is achieved by parallel, separate, Viterbi decoders each processing a pair of symbols for each trellis. A two-decoder embodiment for a base band chip is utilizable for ultra wideband communication.

The present invention relates to convolutional decoding, and more particularly to parallel, Viterbi decoders.

The Viterbi algorithm is widely used in different signal processing systems, such as those pertaining to communication or storage, to decode data transmitted over noisy channels and to correct bit errors.

The algorithm takes advantage of the non-random nature of the incoming bits from the transmitter. The configuration of the convolutional encoder at the transmitter will make some hypothetical bit sequences embodying the output symbols impossible. Distance between the received symbols and feasible bit sequences are measured, and these measurements are cumulated with each receipt of an encoded symbol or “output symbol” to be decoded. The closest sequences are retained each time for the next iteration. After a pre-set number of iterations, sufficient confidence has been built that the determined closest sequence is the correct one.

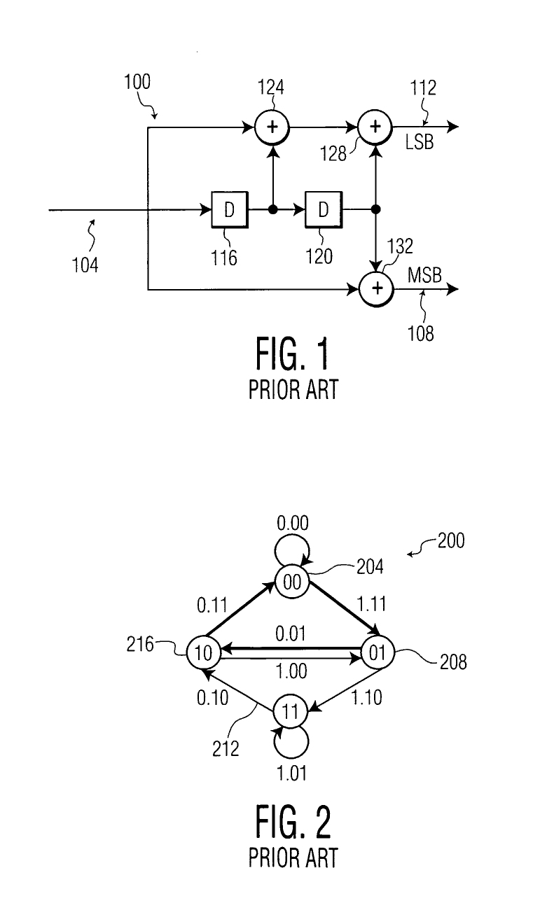

FIG. 1 depicts a simple convolutional encoder 100 for a transmitter of encoded symbols. Its rate is ½ since, for every one input bit 104, two output bits are derived, a most significant bit (MSB) 108 and a least significant bit (LSB) 112. The encoder 100 has two D flip-flops 116, 120, that are mutually clocked to each output a binary value buffered at their respective input with each clock pulse. Three exclusive-OR (XOR) gates 124, 128, 132 perform binary addition to deliver the two output values 108, 112 at each clock pulse based on the input 104 and the buffered input values of the two D flip-flops 116, 120.

FIG. 2 is a state diagram 200 showing the states of the encoder 100 of FIG. 1 and the possible transitions between states. As such, the state diagram 200 defines the encoder 100. The states 204 to 216 are labeled so that the LSB is the one residing in the leftmost flip-flop 116. The branch labels are formatted to show the 1-bit input value 104, separated by a period from the two-bit output 108, 112. The branches in bold will be discussed below in connection with FIG. 4.

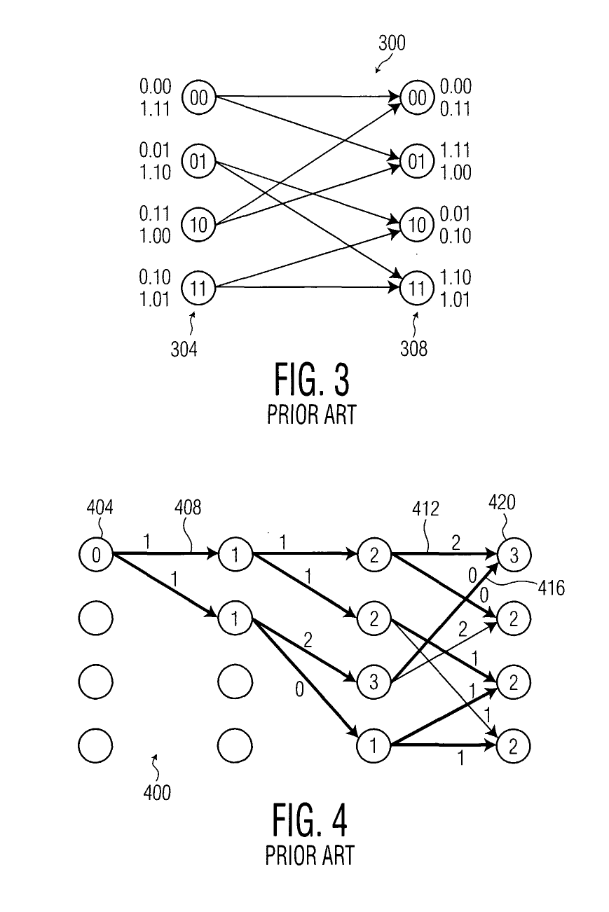

FIG. 3 is a trellis diagram of a trellis stage 300 corresponding to and equivalent to the state diagram 200. The representation of stage 300 includes a left column 304 of states, a right column 308 of states and the branches of the state diagram 200. Branch labels appear to the left or right of the state, rather than on the branch itself. The topmost annotation pertains to the uppermost (or “0”) branch emanating from that state, whereas the bottom annotation pertains to the lower (or “1”) branch.

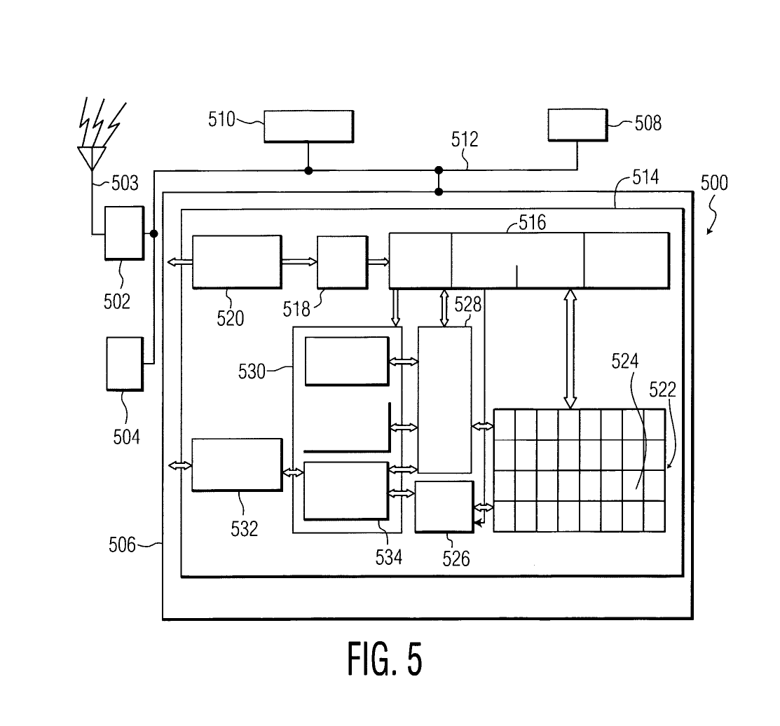

FIG. 4 is a three-stage trellis diagram 400 demonstrating execution of the Viterbi algorithm. It is assumed, for simplicity of demonstration, that the only initially active state is 00, and that the zero within the circle 404 represents a path metric of zero. The path metric is an accumulated measure of distance between received symbols and the currently determined closest sequence of corresponding values subject to the topology of the encoder 100. In this example, it is further assumed that a received sequence of three symbols is 10 10 11. In each stage, a Hamming distance is calculated between the received symbol and the encoder output associated with each branch. The Hamming distance is the sum of the absolute differences between respective bits. Thus, for example, the first symbol is “10” and the output associated with the branch 408, as seen from FIG. 3, is “00.” The Hamming distance is thus 1, which appears over branch 408 in FIG. 5. By the third stage in this simple example, multiple branches lead to the same stage. For instance, the branches 412, 416 lead to state 00. The Viterbi algorithm adds the respective path metrics 2 and 3 to the branch metrics 2 and 0 of the branches 412, 416, respectively, to yield the sums 4 and 3. Since 3 is smaller than 4, 3 becomes the new path metric for state 00, i.e., the path metric for state 00 at stage 3. The number 3 accordingly appears in the circle 420. The prevailing branches appear in bold in stage 3, and belong to the surviving paths. At stage three in this example, three states are tied at 2, but the algorithm tends to converge to a clear survivor of lowest path metric as one proceeds stage-by-stage up to a predetermined truncation length. At that point, the surviving path can be traced back to identify the sequence of respective input bits that was actually transmitted.

In this example, since only one state was initially active, path selection was not required until the third stage. However, once all states are active, path selection occurs at each stage. Although the metric used here was Hamming distance, other metrics such as Euclidean distance may alternatively be used. As a further alternative, trace-back need not be performed if storage is maintained for the current path for each state

Since the data transfer rates in systems using the Viterbi algorithm are steadily increasing, Viterbi decoding is being implemented for rapid processing by means of a semiconductor chip, and its required processing speed is ever rising.

Due to reasons that include power consumption and the cost of complementary metal oxide semiconductor (CMOS) technology, implementing Viterbi decoders in parallel is usually less expensive compared to the bit-serial approach that processes one sample, e.g., bit, per clock cycle, albeit in tradeoff for more silicon area or footprint.

According to one proposal for the upcoming IEEE 802.15-03 or “ultra-wide band” (UWB) standard, a Viterbi decoder should be able to process 480 megabits per second (Mbit/sec) or megahertz (MHz), based on the decoding of a single sample or output symbol per clock. It is, however, preferable to run the system at a much lower frequency, close to ¼ of the 480 MHz required for straightforward implementation. It is especially preferable, since the UWB standard will target even higher data rates (up to 1 gigabit per second (Gbit/s)) in the future.

U.S. Patent Publication 2003/0123579 A1 to Safavi et al., hereinafter “Safavi,” entitled “Viterbi Convolutional Coding Method and Apparatus,” filed on Nov. 15, 2002, runs four separate Viterbi decoders in parallel to increase overall processing speed, but at a cost of power consumption and footprint.

The present invention has been made to address the above-noted shortcomings in the prior art. It is an object of the invention to execute Viterbi decoding at high speed with a reduced footprint penalty. In brief, the present invention involves at least one device for allocating among parallel Viterbi decoders pairs of output symbols of a convolutional encoder. The one or more devices also merge output of the decoders to form a decoded bitstream. Each of the decoders operates according to a trellis stage formed from two constituent trellis stages so that any path metric being updated at that stage is updated no more than once at that stage.

Details of the invention disclosed herein shall be described with the aid of the figures listed below, wherein:

FIG. 1 is a circuit diagram depicting a simple convolutional encoder for a transmitter of encoded symbols;

FIG. 2 is a state diagram for the encoder of FIG. 1;

FIG. 3 is a trellis diagram of a trellis stage representative of the state diagram in FIG. 2 and the encoder in FIG. 1;

FIG. 4 is a three-stage trellis diagram demonstrating execution of the Viterbi algorithm;

FIG. 5 is a block diagram of an embodiment of the present invention;

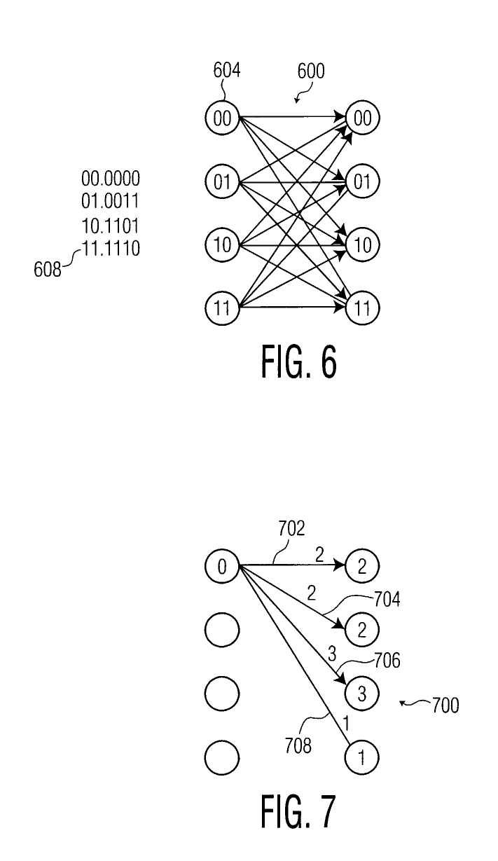

FIG. 6 is a diagram of a trellis stage, based on the encoder in FIG. 1, that processes output symbols in pairs according to the present invention;

FIG. 7 is a trellis diagram that shows a single Viterbi stage representative of two constituent stages in accordance with the present invention;

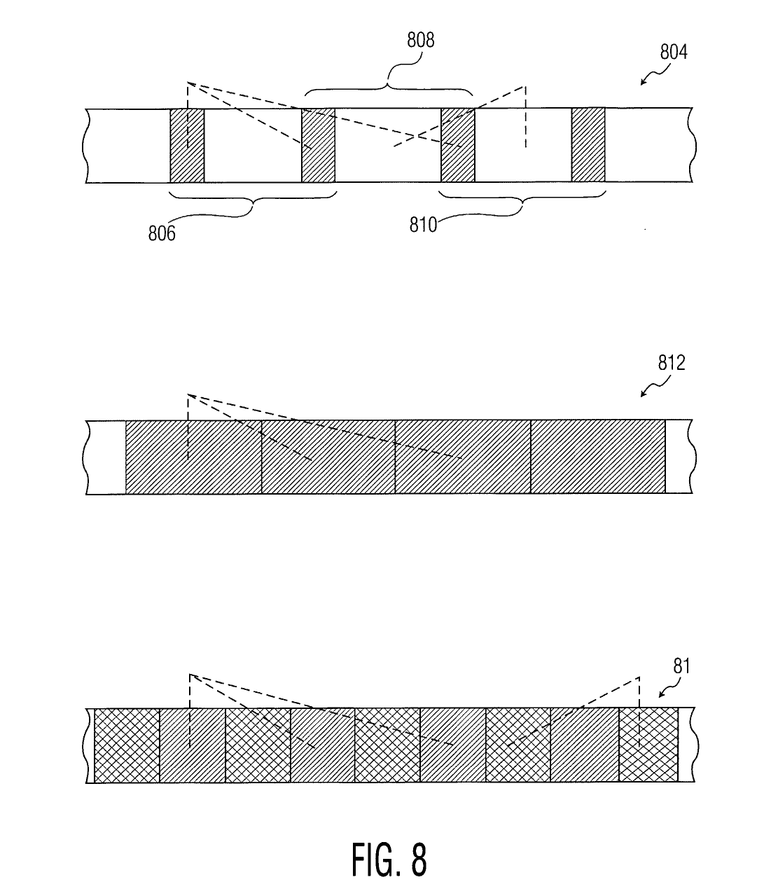

FIG. 8 is a format diagram demonstrating one approach to allocating pairs of output symbols as input to each Viterbi decoder by dividing the incoming stream of output symbol pairs into overlapping blocks, in accordance with the present invention; and

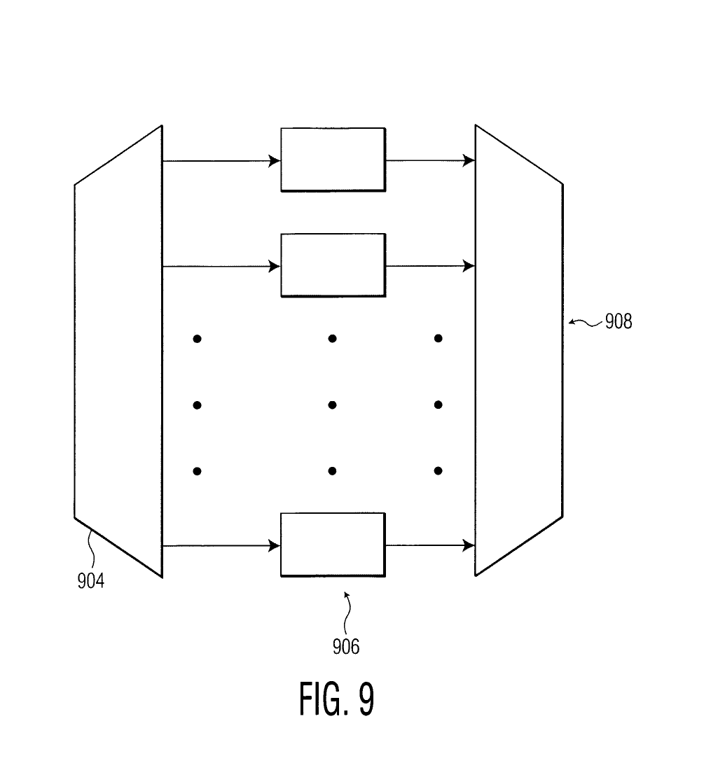

FIG. 9 is another embodiment of the present invention.

There are several limitations in the parallelization potential of the Viterbi algorithm due to its recursive nature. The Viterbi algorithm takes advantage of the non-random nature of the incoming bits from the transmitter. The configuration of the convolutional encoder at the transmitter will make some hypothetical bit sequences embodying the output symbols impossible. Distance between the received symbols and feasible bit sequences are measured, and these measurements are cumulated over symbol time with the closest sequences being retained each time for the next iteration.

Execution speed, for example, is therefore limited by the need to know the accumulated value at symbol time x to calculate the same at symbol time x+1. In other words, the path metric at stage i+1 cannot be calculated until the path metric at stage i is known.

If distance measurement and selection of the closest sequences are performed for two symbols at a time, i.e., upon receipt of every other symbol, the incoming stream of symbols can be handled even if it arrives at the decoder twice as fast. Referring back to FIG. 1, one input bit 104 to encoder 100 produces a single symbol 108, 112. Concurrently decoding symbols that yield 2 decoded bits in total is known as radix-4 decoding, since there are 4 possible values.

Even assuming, however, that each symbol is generated at the convolutional encoder 100 based on a respective, single input bit 104, the above-described aggregating of symbols has been shown to become extremely costly in terms of silicon area if extended beyond mere doubling, e.g., radix N>4.

Coarse grain parallelization, an alternative method of increasing overall processing speed, splits the incoming bitstream into several parallel blocks for processing by several respective independent Viterbi decoders. This technique, too, increases the silicon area significantly.

In accordance with the present invention, the spiraling penalties of scale for both techniques, symbol aggregation and coarse grain parallelization, are mitigated by combining both techniques to achieve an overall processing speed objective with minimal footprint.

FIG. 5 shows, by way of illustrative and non-limitative example, parallel Viterbi decoders embodied in a digital signal processor (DSP) semiconductor chip utilized in the baseband unit of a wireless receiver, in accordance with the present invention. A receiver 500, includes a radio frequency (RF) unit 502 with an antenna 503, and intermediate frequency (IF) unit 504, a baseband unit 506, an input/output (I/O) unit 508 for user interface, audio, etc., and a controller 510, the various units being connected by a data/control bus 512.

A DSP 514 within the baseband unit 506 represents an adaptation of the embodiment of FIG. 3 of the Safavi patent publication number 2003/0123579 that reduces footprint but retains processing speed. The DSP 514 includes: a reduced instruction set computer (RISC) processor 516 with its associated instruction cache 518 and memory controller 520; an RC array 522 comprising an 4-row by 8-column array of RCs 524; a context memory 526; a frame buffer 528; and a direct memory access (DMA) 530 with its coupled memory controller 532. The DMA 530 includes an SC generator, interleaver engine, and a DMA controller 534. Each RC includes several functional units (e.g. MAC, arithmetic logic unit, etc.) and a small register file, and is preferably configured through a 32-bit context word, however other bit-lengths can be employed.

The frame buffer 528 acts as an internal data cache for the RC array 522, and can be implemented as a two-port memory. The frame buffer 528 makes memory accesses transparent to the RC array 522 by overlapping computation processes with data load and store processes. The frame buffer 528 can be organized as 8 banks of N.times.16 frame buffer cells, where N can be sized as desired. The frame buffer 210 can thus provide 8 RCs of a row with data, either as two 8-bit operands or one 16-bit operand, on every clock cycle.

The context memory 526 is the local memory in which to store the configuration contexts of the RC array 522, much like an instruction cache. A context word from a context set is broadcast to all eight RCs 206 in a row. All RCs 206 in a row can be programmed to share a context word and perform the same operation. Thus the RC array 102 can operate in Single Instruction, Multiple Data form (SIMD). For each row there may be 256 context words that can be cached on the chip. The context memory can have a 2-port interface to enable the loading of new contexts from off-chip memory (e.g. flash memory) during execution of instructions on the RC array 522.

The RISC processor 516, which includes fetch, decode, execute and write-back sections, handles general-purpose operations, and also controls operation of the RC array 522. It initiates all data transfers to and from the frame buffer 528, and configuration loads to the context memory 526 through the DMA controller 534. When not executing normal RISC instructions, the RISC, processor 516 controls the execution of operations inside the RC array 522 every cycle by issuing special instructions, which broadcast SIMD contexts to RCs 524 or load data between the frame buffer 528 and the RC array 522. This makes programming simple, since one thread of control flow is running through the system at any given time.

In accordance with an embodiment, a Viterbi algorithm is divided into a number of sub-processes or steps, each of which is executed by a number of RCs 524 of the RC array 522, and the output of which is used by other same or other RCs 524 in the array.

In a preferred embodiment, the top two rows implement a Viterbi decoder and the bottom two rows provide a separate Viterbi decoder to execute a Viterbi decoding in parallel with that of the other decoder. By sacrificing a bit of versatility in converting the Safavi 8×8 array of processing cells to a 4×8 array, power consumption and footprint due to the array are reduced even taking into account processing/storage overhead of double-symbol decoding. Yet, with merely 2 parallel decoders, according to the present invention, processing speed is maintained at a level similar to that of the 4 parallel decoders in Safavi.

FIG. 6 shows a trellis stage 600, based on the encoder 100 in FIG. 1, that processes output symbols in pairs according to the present invention. Referring back to FIG. 3, the trellis stage 600 has two constituent trellis stages 300. The constituent trellis stages 300 are consecutive, so that the trellis stage 600 represents two clock pulses, i.e., two input symbols and two output symbols. Accordingly, starting from the top and proceeding downward, each of the four branches from state 00 in stage 600 corresponds to a respective annotation to the left of the circle 604 representing state 00. The bottom annotation 608, for example, shows that the first output symbol is “11,” the second output symbol is “10” and both respective input bits 104 are one. Starting, therefore, from state “00” and tracing through two iterations of stage 300 leads to state “11,” which matches what is shown by the trellis stage 600 in FIG. 6. Each of the source and destination states of stage 600 has four branch annotations. Although in the present example there are four branches coming from or leading to each state due to the structure of encoder 100, a different encoder might have fewer branches coming from or leading to any given state.

FIG. 7 shows a single stage 700 representative of two constituent stages of the Viterbi algorithm collapsed to form the single stage in accordance with the present invention. In particular, stage 700 corresponds to the first two stages of FIG. 4. Since the Hamming metric is used in this example, the branch metrics 702 to 708 of FIG. 7 are equal to the respective sums of branch metrics in FIG. 4. This latter equivalence would not hold if the metric used were Euclidean distance, for example. Each stage corresponds to a single branch metric 702, 704, 706, 708 from any active state and further corresponds to a single path metric update for any state receiving a branch. Each stage also corresponds to single iteration of any trace back procedure. Accordingly, processing speed is essentially doubled by processing output symbols in pairs. Corresponding modifications to the Safavi DSP include adapting branch metric calculations for pairs of symbols, assigning two rather than one bit to each state for trace-back, etc.

It is noted that the invention is not limited to any particular branch metric or trace-back architecture. Moreover, although the embodiment of FIG. 5 is implemented with two separate, parallel Viterbi decoders, any number of two or more such encoders is within the intended scope of the invention. Therefore, for example, a full 8×8 array may be utilized to realize four radix-4 decoders and to thereby afford approximately double the processing speed of the Safavi device.

FIG. 8 demonstrates one approach to allocating pairs of output symbols as input to each Viterbi decoder by dividing the incoming stream of output symbol pairs into overlapping blocks, in accordance with the present invention. These techniques are detailed in the pending, commonly-assigned, U.S. Patent Application ID 609443, entitled “Parallel Implementation for Viterbi-Based Detection Method,” the disclosure of which is incorporated by reference herein in its entirety. Merging scheme 804 shows the end portion of each Viterbi block 806, 808, 810 overlapping the starting portion of the next block. At least one pair of output symbols is common to both overlapping blocks and resides in the overlap portion. In merging scheme 812, the overlap between one block and the next covers half the block. Merging scheme 816 shows an overlap of more than half the block, with at least one pair of symbols in a three-way overlap portion.

Alternatively, when dividing the incoming stream into blocks for respective parallel Viterbi decoding, the blocks may be allocated in a non-overlapping manner. For example, a zero-shift method is disclosed in “Algorithms and Architectures for Concurrent Viterbi Decoding,” IEEE, to Lin et al., 1989. In the zero-shift method, the shift register in the encoder, corresponding to the two flip-flops 116, 120 in FIG. 1, are periodically loaded with zeroes to return to ground state at the end of each block. An alternative method discussed in Lin is the reset method, which actually overwrites stored values in the shift register periodically.

Safavi discusses, in connection with a single Viterbi decoder, pipeline processing of the state metrics computation and the trace back computation on respectively overlapping input blocks, and, as a preferred alternative, a sliding window technique which eliminates the need for overlap. Either of these methods may be adapted for parallel decoders as well.

The present invention is not limited to implementation by means of an array processor such as the Safavi embodiment. Instead, and as shown in FIG. 9, a demultiplexer (demux) unit 904 may, for example, be used to allocate blocks to multiple Viterbi decoders 906, the output being merged by a separate, multiplexer unit 908 to form a decoded bitstream. Here, each Viterbi unit 906 may, for instance, perform its respective Viterbi decoding independently of other units 906.

Also provided by the present invention is an apparatus and method for testing or prototyping a system that includes, along with the Viterbi decoders, a component capable of handling higher bandwidth than a single decoder. The combined performance of the Viterbi decoders allows the testing or prototyping to occur. The RF unit 502 of FIG. 5, for example, can be tested in the receiver 500 even the unit's bandwidth capability exceeds that of one decoder, as long the combined bandwidth of the decoders is sufficient.

The inventive decoding apparatus also finds application in optical disc systems, such as SFFO, DVD, DVD+RW, Blu-ray disc; magneto-optical systems such as a mini disc; hard storage systems; and digital tape storage systems, both professional and consumer.

While there have been shown and described what are considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

1. A Viterbi decoding apparatus comprising:
at least one device for allocating among plural, parallel Viterbi decoders pairs of output symbols of a convolutional encoder and for merging output of the plural decoders to form a decoded bitstream; and
the plural decoders, each configured with a trellis stage formed from two constituent trellis stages so that any path metric being updated at said stage is updated no more than once at said stage.

2. The apparatus of claim 1, wherein one of the symbols of a pair has been generated in a clock cycle of said encoder that consecutively follows a clock cycle in which the other was generated.

3. The apparatus of claim 1, wherein a decoder of the plurality is configured so that such an updated path metric has been updated at said stage by a branch metric calculated using both of the symbols of a single such pair.

4. The apparatus of claim 1, wherein the constituent trellis stages are consecutive and identical.

5. The apparatus of claim 1, wherein each constituent trellis stage defines the convolutional encoder.

6. The apparatus of claim 1, configured with a total of two decoders.

7. The apparatus of claim 6, wherein said encoder inputs a single bit for each of said output symbols.

8. The apparatus of claim 1, wherein the pairs are divided among blocks, said allocating allocates the blocks to respective ones of the decoders, each block having a beginning and an end, the end of one block overlapping, content-wise, the beginning of a next block to form corresponding overlap regions of the two blocks, said regions having at least one of said pairs in common.

9. The apparatus of claim 1, wherein the pairs are divided among non-overlapping blocks, wherein said allocating allocates the blocks to respective ones of the decoders.

10. A Viterbi decoding method comprising the steps of:
allocating among plural, parallel Viterbi decoders pairs of output symbols of a convolutional encoder;
operating the plural decoders with a trellis stage formed from two constituent trellis stages so that any path metric being updated at said stage is updated no more than once at said stage; and
merging output of the plural decoders to form a decoded bitstream.

11. The method of claim 10, wherein one of the symbols of a pair has been generated in a clock cycle of said encoder that consecutively follows a clock cycle in which the other was generated.

12. The method of claim 10, wherein the operating step further comprises the step of updating said any such path metric from a single, respective branch metric derived from both of the output symbols of a pair of said pairs.

13. The method of claim 10, wherein the constituent trellis stages are consecutive and identical.

14. The method of claim 10, wherein each constituent trellis stage defines the convolutional encoder.

15. The method of claim 10, wherein the plurality of decoders consists in total of two decoders.

16. The method of claim 15, wherein said encoder inputs a single bit for each of said output symbols.

17. A method for testing a system that includes the plural decoders of claim 10 using the method of claim 10, wherein a component of the system is capable of operating at a higher bandwidth than a decoder of the plural decoders, further comprising the steps of:
providing said system; and
operating said system using said Viterbi decoding method, said higher bandwidth being accommodated by concurrent performance of the plural decoders.

18. The method of claim 17, wherein the component is disposed upstream of the plural Viterbi decoders.

19. The method claim 10, wherein the allocating step includes the step of dividing the pairs among blocks so that said allocating allocates the blocks to respective ones of the decoders, each block having a beginning and an end, the end of one block overlapping, content-wise, the beginning of a next block to form corresponding overlap regions of the two blocks, said regions having at least one of said pairs in common.

20. The method of claim 10, wherein the allocating step includes the step of dividing the pairs among non-overlapping blocks so that said allocating allocates the blocks to respective ones of the decoders.
